(19) United States
(12) Patent Application Publication
(10) Pub. No.: US 2008/0237652 A1
(43) Pub. Date: Oct. 2, 2008

(54) Method of Manufacturing a Solid Image Pick-Up Device and a Solid Image Pick-Up Device

(76) Inventors: Teiji Azumi, Miyagi (JP); Takanori Sato, Miyagi (JP)

Correspondence Address: BIRCH STEWART KOLASCH & BIRCH, PO BOX 747, FALLS CHURCH, VA, 22040-0747, US

(21) Appl. No.: 10/570,146

(22) PCT Filed: May 19, 2005
(86) PCT No.: PCT/JP2005/009579

§ 371 Date: Mar. 1, 2006

(30) Foreign Application Priority Data
May 21, 2004 (JP) 2004-151845
May 18, 2005 (JP) 2005-145749

(51) Int. Cl. H01L 27/148; H01L 21/768

(52) U.S. Cl. 257/231; 438/98; 257/E27.152; 257/E21.576

(57) ABSTRACT

A method of manufacturing a solid image pick-up device comprising a photoelectronic conversion portion, a charge transfer portion and a peripheral circuit portion, the method comprising:
forming a pattern comprising a first layer silicon conductive film to a surface of a semiconductor, the first layer silicon conductive film forming: a first electrode; and a first layer interconnection for the photoconductive conversion portion and the peripheral circuit portion; forming an insulative film at least to a side wall of the first electrode; forming a second silicon conductive film being to form a second electrode to the semiconductor substrate; coating a resist over the semiconductor substrate by a spin coating method; and planarizing the second layer silicon conductive film by a resist etching-back method,
wherein the pattern further comprises at least one dummy pattern, and a surface level of the resist is not below a predetermined value over the semiconductor substrate.

### TECHNICAL FIELD

The present invention concerns a method of manufacturing a solid image pick-up device, and a solid image pick-up device and, particularly, it relates to a solid image pick-up device of a single layered electrode CCD (charge-coupled device) structure.

### BACKGROUND ART

A solid image pick-up device using a CCD used, for example, in an area sensor comprises a photoelectronic conversion portion such as a photodiode and a charge transfer portion having a charge transfer electrode for transferring signal charges from the photoelectronic conversion portion. Charge transfer electrodes are arranged in plurality adjacent with each other on a charge transfer channel formed to a semiconductor substrate and driven successively.

In recent years, a demand for higher resolution and higher sensitivity for solid image pick-up devices has been increased more and more and increase for the number of image pick-up pixels has been proceed as far as giga pixels or more. A substrate (silicon substrate) to which a solid image pick-up device is prepared is stacked with a filter or a lens and mounted. Accordingly, a positional accuracy between the lens and the photoelectronic conversion portion is important, and the distance, that is, the distance in the direction of the height thereof provides a significant problem in view of the positional accuracy in manufacturing steps and in view of the sensitivity during use (photoelectronic conversion efficiency).

Further, under the situations described above, it is necessary for higher integration degree by reducing the area per unit pixel in order to obtain a high resolution without enlarging the tip size. On the other hand, since the sensitivity is lowered as the area for the photodiode constituting the photoelectronic conversion portion decreases, the area for the photodiode region has to be ensured.

Then, various studies have been made for refining tips while ensuring the area occupied by the photodiode region by refining interconnections in the charge transfer portion and peripheral circuit thereby decreasing the area ratio of the interconnections.

Under the situation described above, for attaining higher integration by refinement of interconnections, it is an important technical subject to keep planarity for an inter-layer insulative film between interconnection layers. In view of the above, for improving the planarity, a structure of making the charge transfer portion to a single layered electrode structure has been proposed (for example, JP-A No. Hei 11-26743).

By the way, in an existent solid image pick-up device of using a charge transfer electrode of a single layered structure, a single layered structure of the electrode is prepared by using a polycrystal silicon or amorphous silicon layer as a charge transfer electrode, forming a first layer interconnection, then oxidizing the patterned surface of the first layer interconnection, depositing a polycrystal silicon or amorphous silicon layer as a transfer electrode at the second layer, coating a resist, and conducting entire surface etching by a resist etching-back method.

For example, in the existent method, a silicon oxide film 2a of 15 to 35 nm thickness, a silicon nitride film 2b of 50 nm thickness and a silicon oxide film 2c of 10 nm thickness are formed to the surface of an n-type silicon substrate 1 to form a gate oxide film 2 of a three layered structure.

Successively, a doped amorphous silicon film 3a as the first layer is formed on the gate oxide film 2 and then a silicon oxide film 4 and a silicon nitride film 5 are formed. Successively, a resist is coated over the layer.

Then, as shown in FIG. 9A, exposure is conducted by photolithography using a desired mask and development and water washing are conducted to form a resist pattern R1 with a pattern width of from 0.3 to several μm. The pattern width may be 0.3 μm or less.

Then, as shown in FIG. 9B, the silicon oxide film 4 and the silicon nitride film 5 are etched by using the resist pattern R1 as a mask to form a mask pattern for patterning the first electrode.

Then, the resist pattern is peeled and removed by ashing (FIG. 9C), and a doped amorphous silicon film 3a as the first layer is selectively removed by etching using the mask pattern as a mask and using the silicon nitride film 2b of the gate oxide film 2 as an etching stopper to form a first electrode (FIG. 9D).

Successively, an inter-layer insulative film 6 is formed to the surface of the first electrode pattern by thermal oxidation (FIG. 10A), and a doped second layer amorphous silicon film 3b is formed thereover (FIG. 10B).

Then, a resist R2 is coated over the entire surface (FIG. 10C), and the second doped amorphous silicon film 3b is planarized by resist etching-back (FIG. 10D).

Then, as shown in FIG. 11A, a desired resist pattern R3 is applied for covering.

Subsequently, the doped second layer amorphous silicon film 3b over the photodiode region 30 is selectively removed by etching using the resist pattern R3 as a mask.

Then, as shown in FIG. 11B, the resist pattern R3 is eliminated by ashing.

Thus, a second electrode comprising the doped second layer amorphous silicon film 3b is formed to form a solid image pick-up device electrode with a planar surface.

In the case of this method, when a charge transfer electrode of a single layer structure is manufactured by etching-back the doped second layer amorphous silicon film, the resist is coated by spin coating over the second layer polycrystal silicon film 3b and etched such that the etching rate is about identical for the resist and the doped second layer amorphous silicon film to planarize the surface.

However, in a case where a region of the first doped amorphous silicon film of low density is present at the circumferential periphery of a wafer, when the resist is formed by spin coating, the surface level of the resist R2 is lowered as shown in FIG. 10C and, as a result, this causes film reduction of the doped second layer amorphous silicon film at the peripheral edge of the wafer as shown in FIG. 11B.

Further, in a region where the density of the doped amorphous silicon film is low, such as the interconnection portion or a region other than the photodiode portion on the semiconductor substrate, a region where the resist is thin is sometimes formed between the patterns not restricted to the wafer circumferential etch. This results in a problem of scattering for the interconnection resistance in such a case.

In the case as described above, there was a problem of scattering for the interconnection resistance at the periphery. Further more, the transfer efficiency is sometimes degraded due to the scattering of the film thickness for the charge transfer electrode at the periphery. Then, this results in unevenness for the thickness and the variation of the shape in various kinds of films such as a planarized film, micro lens, color filter, etc. above the charge transfer electrode and they also result in a problem of shading, scattering of sensitivity and worsening of smear by stray light.

Accordingly, the method described above involves a problem that it is difficult to cope with the further improvement of the sensitivity.

As described above, existent solid image pick-up devices involve a problem that the thickness of the doped second layer amorphous silicon film is decreased in a region of the first electrode constituting the first layer over the semiconductor substrate where the pattern density is small, particularly, in the circumferential periphery of the wafer.

### DISCLOSURE OF THE INVENTION

The invention has been achieved in view of the forgoing situations and in a case of forming a charge transfer electrode of a single layered electrode structure by forming a second layer conductive film over the pattern of the first layer conductive film and removing the second layer conductive film over the first layer conductive film for planarization, it intends to improve the charge transfer efficiency by preventing the film reduction caused by the resist etching-back step for planarization thereby improving the charge transfer efficiency.

According to the invention, there is provided a method of manufacturing a solid image pick-up device comprising a photoelectronic conversion portion, a charge transfer portion having a charge transfer electrode of a single layered electrode structure for transferring charges generated in the photoelectronic conversion portion and a peripheral circuit portion connected with the charge transfer portion, the method comprising: a step of forming a pattern comprising a first layer silicon conductive film to a surface of a semiconductor substrate on which a gate oxide film is formed, the first layer silicon conductive film forming: a first electrode; and a first layer interconnection for the photoconductive conversion portion and the peripheral circuit portion; a step of forming an insulative film as an inter-electrode insulative film at least to a side wall of the first electrode, so as to produce a first electrode/inter-electrode insulative film-formed semiconductor substrate; a step of forming a second silicon conductive film to a surface of the first electrode/inter-electrode insulative film-formed semiconductor substrate, the second silicon conductive film being to form a second electrode, so as to produce a second silicon conductive film-formed semiconductor substrate; a step of coating a resist over the second silicon conductive film-formed semiconductor substrate by a spin coating method; and a step of planarizing the second layer silicon conductive film by a resist etching-back method, wherein the pattern further comprises at least one dummy pattern, and the step of forming the pattern comprises a step of forming said at least one dummy pattern such that a surface level of the resist is not below a predetermined value over the semiconductor substrate.

In a region where the pattern density is small, such as an interconnection portion and a region other than the photo diode portion over the semiconductor substrate, particularly, in the wafer peripheral region, the film thickness of the resist is decreased tending to lower the surface level. In the constitution described above, since the surface level can be kept from lowering even in the peripheral portion prior to the resist etching-back by the addition of the dummy pattern, film reduction of the silicon conductive film, particularly, the second layer silicon conductive film caused upon making the charge transfer electrode into a single layered structure. Accordingly, since the charge transfer electrode and the peripheral circuit of uniform film thickness can be formed, it is possible to prevent scattering of device characteristics and form a highly reliable solid image pick-up device. Upon spin coating the resist, the surface level of the resist tends to be lowered at the wafer peripheral portion, and it is desirable to improve the surface level of the resist by the dummy pattern in a region where the surface level of the resist tends to be lower also in the region other than the peripheral portion.

Further, in the method according to the invention, said at least one dummy pattern are formed such that area density of said at least one dummy pattern is substantially equal to or more than that of the first layer interconnection for the photoelectronic conversion portion.

According to this constitution, since the dummy pattern is added to the first layer silicon conductive film constituting the first layer interconnection as an underlayer so as to have a density about equal with or more than that of the first layer interconnection of the photodiode region, this can prevent the lowering of the surface level for the photoresist on the surface of the semiconductor substrate to prevent film reduction of the second layer silicon conductive film.

Further, in the method according to the invention, said at least one dummy pattern are formed such that distance between said at least one dummy pattern is substantially equal to or less than interconnection distance of the first layer interconnection for the photoelectronic conversion portion.

Further, the method according to the invention further comprises a step of etching to remove partially said at least one dummy pattern after the step of planarizing.

This constitution can avoid the effects given to the circuit operation.

Further, in the method according to the invention, said at least one dummy pattern is electrically connected with each other. This constitution felicitates the connection of the dummy pattern to a desired potential.

Further, in the method according to the invention, said at least one dummy pattern is in a network-shape.

According to this constitution, each of the cells can be connected, for example, to a conductor kept at a desired potential such that noises give no effects on the circuit operation.

Further, in the method according to the invention, said at least one dummy pattern comprises at least one first dummy pattern located in a region adjacent with the second electrode, and each of said at least one first dummy pattern is an isolated pattern.

According to the constitution, it is possible not only to prevent film reduction at the peripheral portion but also prevent short circuit with the second electrode by making the dummy pattern as an isolated pattern.

Further, the method according to the invention further comprises: a step of forming a trench to the surface of the semiconductor substrate in a region for forming a field oxide film disposed to the peripheral circuit portion and the charge transfer portion, so as to surround an effective image pick-up region of the photoelectronic conversion portion, prior to forming the charge transfer portion; a step of forming the field oxide film in the trench; a surface planarization step of planarizing the surface of the semiconductor substrate to which the field oxide film is formed; and a step of forming a device portion including the charge transfer electrode, the photoelectronic conversion portion and the peripheral circuit portion to the surface of the semiconductor substrate.

The surface can be furthermore planarized easily by the method. In this case, when the depth of the trench and the thickness of the field oxide field can be formed such that they are identical to each other, the planarizing step is not sometimes particularly necessary.

Further, in the method of manufacturing the solid image pick-up device according to the invention, the step of forming the field oxide film comprises a selective oxidation (LOCOS) step.

According to this method, a field oxide film of good film quality can be formed although it a requires long time.

Further, in the method of manufacturing the solid image pick-up device according to the invention, the step of forming the field oxide film comprises a step of filling an insulative film to the trench by a CVD method.

According to the method, the time required for forming the field oxide film can be shortened. Incidentally, the insulative film can be filled by a spin coating method in place of the CVD method.

In the method of manufacturing the solid image pick-up device according to the invention, the surface planarization step of planarizing the surface of the semiconductor substrate comprises: a step of coating a resist to the surface of the semiconductor substrate by a spin coating method; and a step of planarization by a resist etching-back method

Further, in the method of manufacturing the solid image pick-up device according to the invention, wherein the surface planarization step of planarizing the surface of the semiconductor substrate comprises a step of planarizing the surface of the semiconductor substrate by a CMP (Chemical mechanical polishing) method.

Further, in the method of manufacturing the solid image pick-up device according to the invention, the method further comprises a step of forming a stopper layer as an etching stopper to a surface of the first electrode, prior to the step of forming the second silicon layer conductive film, wherein the step of planarizing is a step of conducting etching-back by using the stopper layer as a stopper.

With the constitution described above, since etching-back can be stopped on the first electrode without scraping the first electrode, a charge transfer portion with good planarity and at high yield can be formed. In a case of constituting the second layer conductive film with a silicon conductive film, it is preferred to use silicon nitride or the like. Further, for patterning the first electrode, by using a two layered film of silicon oxide and silicon nitride as a mask and using the same as an etching stopper while leaving the mask as it is, favorable patterning can be conducted without increasing the number of steps and a charge transfer portion of excellent planarity can be formed. The film of silicon nitride also works as an antireflective film in an exposure step for pattering a film formed above the film of silicon nitride.

Further, the present invention provides a solid image pick-up device comprises: a photoelectronic conversion portion; a charge transfer portion having a charge transfer electrode transferring charges generated in the photoelectronic conversion portion; and a peripheral circuit portion connected to the charge transfer portion, wherein the charge transfer electrode has a single layered electrode structure comprising: a first electrode including a first layer silicon conductive film; and a second electrode including a second layer silicon conductive film formed by way of an inter-electrode insulative film covering a side wall of the first electrode, an interconnection of the peripheral circuit portion comprises a first layer silicon conductive film, wherein the solid image pick-up device further comprises at least one dummy pattern constituted so as not to be spaced by a predetermined distance or more from the interconnection of the peripheral circuit portion, and constituted to be at such a potential as giving no electric effect on the first electrode.

Further, in the solid image pick-up device according to the invention, said at least one dummy pattern is in a network shape.

Since this may be formed by the repetition of the pattern identical with the pattern of the charge transfer electrode constituting the conductive channel, it is possible to form a pattern which is easy to form and at high accuracy. The network shape may be a honeycomb or rectangular shape.

### BRIEF DESCRIPTION OF THE DRAWING

FIGS. 1A to 1D are views showing a step of manufacturing a solid image pick-up device of a first embodiment according to the present invention.

FIGS. 2A to 2C are views showing a step of manufacturing the solid image pick-up device of the first embodiment according to the invention.

FIGS. 3A to 3C are views showing a step of manufacturing the solid image pick-up device of the first embodiment according to the invention.

FIG. 4 is a view showing a solid image pick-up device of the first embodiment according to the invention.

FIG. 5 is a cross sectional view showing a solid image pick-up device of the first embodiment according to the invention.

FIG. 6 is a plane view showing a dummy pattern of a solid image pick-up device of the first embodiment according to the invention.

FIGS. 7A to 7D are views showing a step of manufacturing a solid image pick-up device of a second embodiment according to the present invention.

FIGS. 8A and 8B are views showing a step of manufacturing a solid image pick-up device of a third embodiment according to the present invention.

FIGS. 9A to 9D are views showing a step of manufacturing a solid image pick-up device of the prior art.

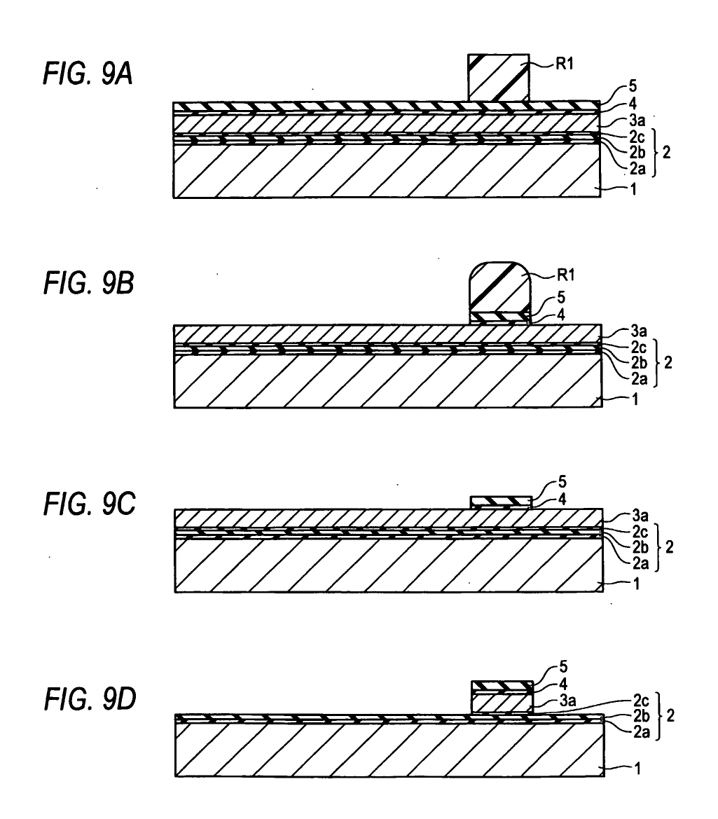

FIGS. 10A to 10D are views showing a step of manufacturing a solid image pick-up device of the prior art; and

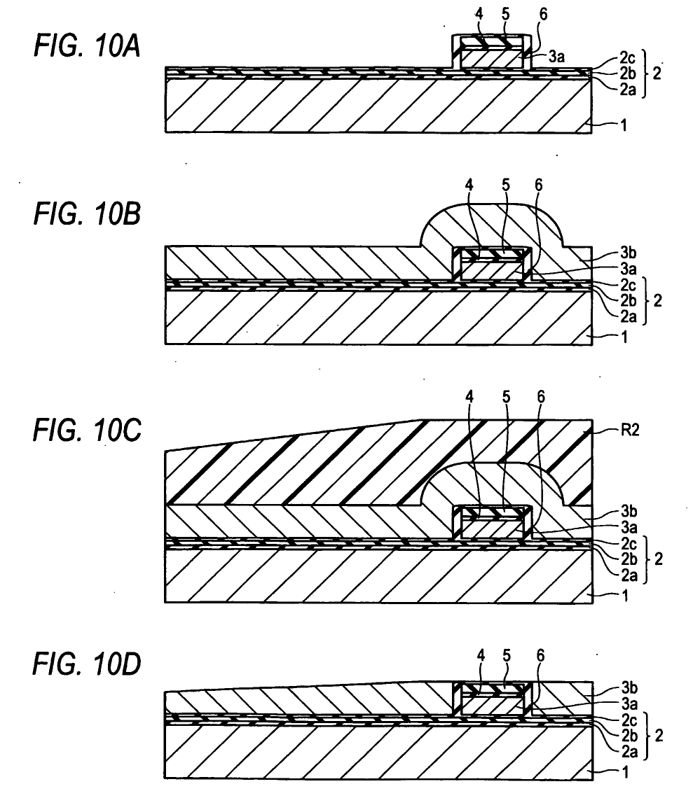

FIGS. 11A and 11B are views showing a step of manufacturing a solid image pick-up device of the prior art.

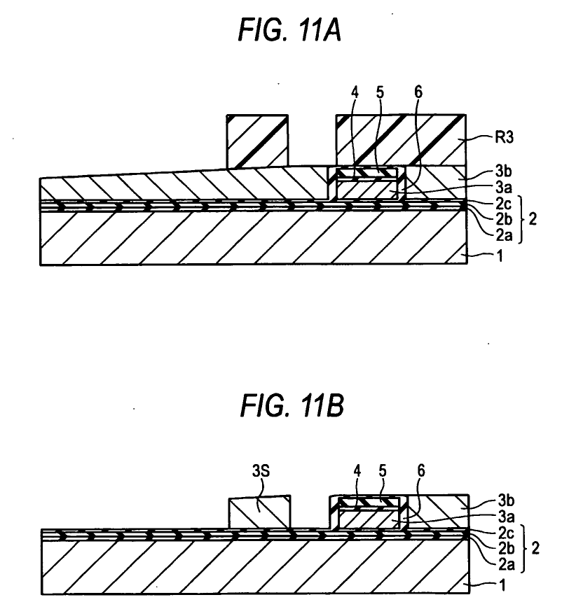

1 denotes a silicon substrate, 2 denotes a gate oxide film, 3a denotes a first electrode (doped first layer amorphous silicon film), 3b denotes a second electrode (doped second layer amorphous silicon film), 3 denotes a charge transfer electrode, 4 denotes a silicon oxide film, 5 denotes a silicon nitride film, 6 denotes an inter-electrode, 7 denotes an insulative film, 30 denotes a photodiode region, 40 denotes a charge transfer portion, 50 denotes a color filter, 60 denotes a micro-lens and 70 denotes an intermediate layer

### BEST MODE FOR CARRYING OUT THE INVENTION

Preferred embodiments of the invention are to be described with reference to the drawings.

### First Embodiment

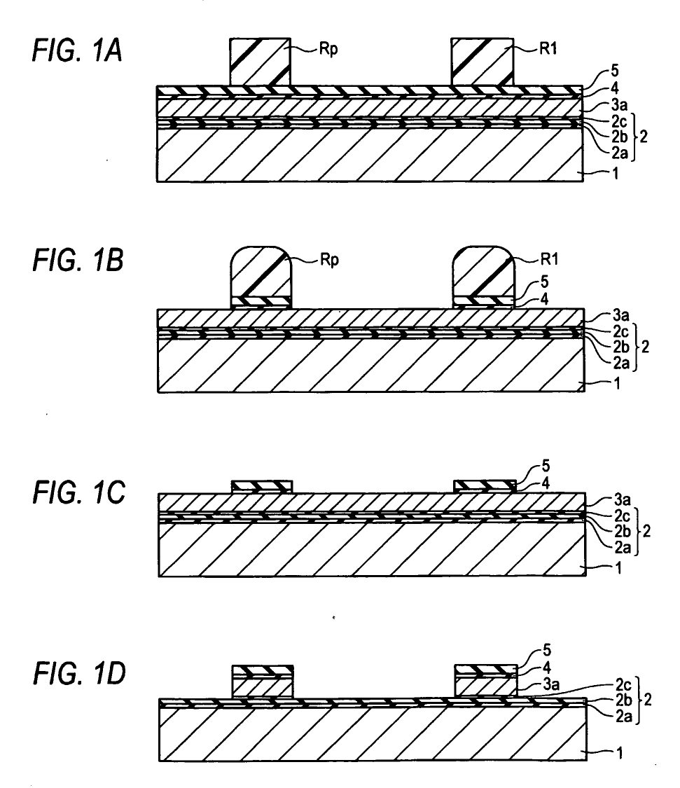

The solid image pick-up device has a feature, as shown by an electrode forming step in FIGS. 1A to 1D to FIGS. 3A and 3B, has a constitution in that a pattern of a first layer amorphous silicon film constituting a first electrode has a dummy pattern at the periphery of a semiconductor substrate upon forming a solid image pick-up device having a charge transfer electrode of a single layered electrode structure, and the pattern distance is not larger at the periphery of the semiconductor substrate than the inter-electrode distance of the first electrode.

Thus, film reduction is not caused to the periphery also for the second electrode and the interconnection constituted with a second layer amorphous silicon by planarization by resist etching-back. Accordingly, in the charge transfer portion and the peripheral circuit portion, surface can be planarized satisfactorily with no film reduction.

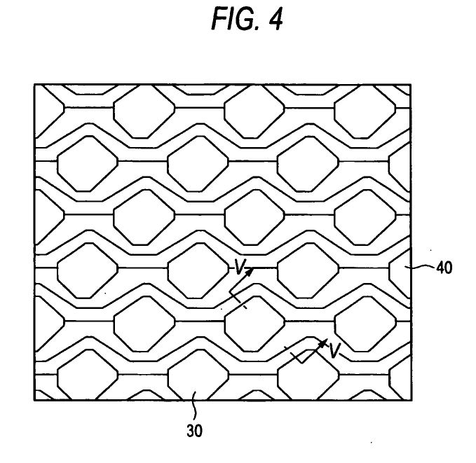

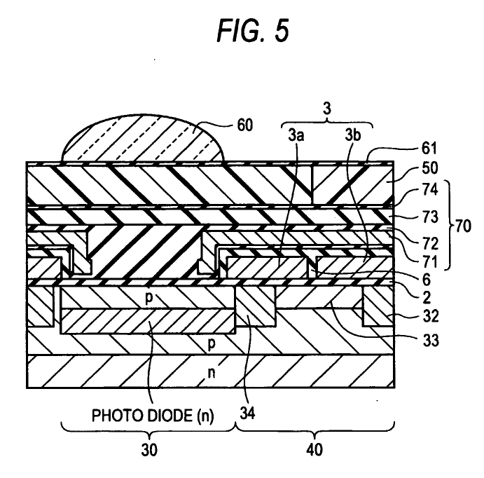

As shown in FIG. 4 and FIG. 5 for the entire outlined explanatory view (peripheral portion is not shown in the drawings), plural diode regions 30 are formed to a silicon substrate 1, and a charge transfer portion 40 for transporting signal charges detected by the photodiode is formed between the photodiode regions. FIG. 5 is a cross sectional view taken along line V-V in FIG. 4.

While a charge transfer channel 33 in which signal charges transferred by the charge transfer electrode move is not illustrated in FIG. 4, it is formed in the region crossing the extending direction of the charge transfer portion 40.

In FIG. 4, inter-electrode insulative films 6 formed near the boundary between the photodiode region and the charge transfer portion 40 are not shown.

As shown in FIG. 5, a photodiode region 30, a charge transfer channel 33, a channel stop region 32, and a charge reading region 34 are formed in the silicon substrate 1, and a gate oxide film 2 is formed over the silicon substrate 1. An inter-electrode insulative film 6 comprising a silicon oxide film and a charge transfer electrode (a first electrode comprising a doped first layer amorphous silicon film 3a and a second electrode comprising a doped second layer amorphous silicon film 3b) are formed over the surface of the gate oxide film 2.

The charge transfer portion 40 is as has been described above and, as shown in FIG. 5, an intermediate layer 70 is formed to the upper surface of the charge transfer electrode of the transfer portion 40, in which are shown a light shield film 71, an insulative film 72 comprising BPSG (borophospho silicate glass), an insulative film (passivation film 73) comprising P—SiN and a planarized layer 74 comprising a transparent resin film.

Above the solid image pick-up device, the light shield film 71 is formed excluding a light detection portion of the photodiode region 30, and a color filter 50 and a micro lens 60 are further formed. Further, a planarized layer 61 comprising, for example, an insulative transparent resin is filled between the color filter 50 and the micro lens 60.

Further, while the solid image pick-up device of a so-called honeycomb structure is shown in FIG. 5, it is of course applicable also to a tetragonal lattice type solid image pick-up device.

Then, a step of manufacturing the solid image pick-up device is to be described specifically.

At first, a silicon oxide film 2a of 15 to 35 nm thickness, a silicon nitride film 2b of 50 nm thickness, and a silicon oxide film 2c of 10 nm thickness are formed on an n-type silicon substrate 1 at a impurity concentration of about 1.0×10¹⁶ cm⁻³ to form a gate oxide film 2 of a 3-layered structure.

Successively, a phosphorous doped first layer amorphous silicon film 3a of 0.4 μm thickness is formed by a vacuumed CVD method using SiH₄ with addition of PH₃ and N₂ as a reactive gas over the gate oxide film 2. The substrate temperature in this step is at 600 to 700° C.

Then, a silicon oxide film 4 of 15 nm thickness and a silicon nitride film 5 of 50 nm thickness are formed by a vacuum CVD method (FIG. 1A).

Successively, a positive resist is coated thereabove to a thickness of 0.5 to 1.4 μm, exposed by photo lithography using a desired mask and then development and water washing are conducted to form a resist pattern R_{D} and a dummy (resist) pattern R1 and a dummy (resist) pattern R_{D} (FIG. 1B). The dummy pattern is formed upon layout such that the distance from the resist pattern R1 does not exceed a predetermined width (first electrode distance) at the periphery of the silicon substrate 1.

Then, the silicon oxide film 4 and the silicon nitride film 5 are etched by reactive ion etching using a gas mixture of CHF₃, C₂F₆, O₂, and He to form a mask pattern for patterning the doped first layer amorphous silicon film 3a. Also in this case, the dummy mask pattern is formed on the left of the mask pattern for forming the first electrode.

Then, the resist pattern is peeled and removed by ashing (FIG. 1C). In this step, a dummy pattern is formed on the left of the usual first electrode pattern in addition thereto for the doped first layer amorphous silicon film 3a.

Then, the doped first layer amorphous silicon film 3a is removed selectively by etching using the mask pattern as a mask and the silicon nitride film 2b of the gate oxide film 2 as an etching stopper by reactive etching using a gas mixture of HBr and O₂ to form interconnections for the first electrode and the peripheral circuit (FIG. 1D). In this case, it is desirable to use an etching apparatus such as of an ECR (Electron Cyclotron Resonance) system or ICP (Inductively Coupled Plasma) system.

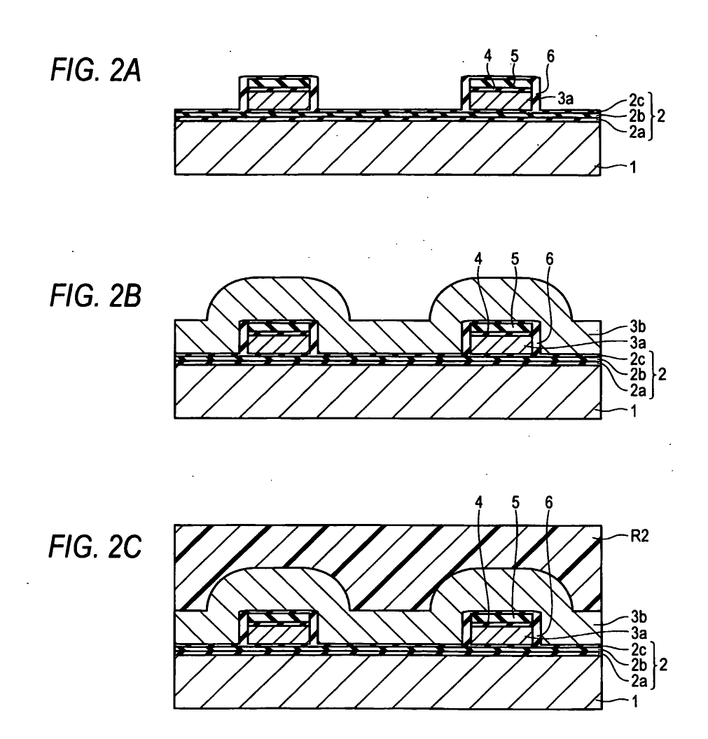

Successively, an inter-electrode insulative film 6 comprising a silicon oxide film of 80 nm thickness is formed to the lateral surface of the first electrode pattern by an oxidizing method (FIG. 2A).

Then, a doped second layer amorphous silicon film 3b of 0.4 to 0.7 μm thickness is formed by a vacuum CVD method using a reactive gas comprising SiH₄ gas with addition of PH₃ and N₂ (FIG. 2B). In this case, it is necessary that the film thickness of the doped second layer amorphous silicon film 3b is about equal with or more than the total thickness for the thickness of the doped first layer amorphous silicon film, and the silicon oxide film 4 and the silicon nitride film 5 thereover.

Then, as shown in FIG. 2C, a resist R2 is coated to the surface where the doped second layer amorphous silicon film 3b is formed, such that the surface level is completely planarized. In this step, OFPR 800 is used as the resist R2 and coated to 700 to 800 nm thickness.

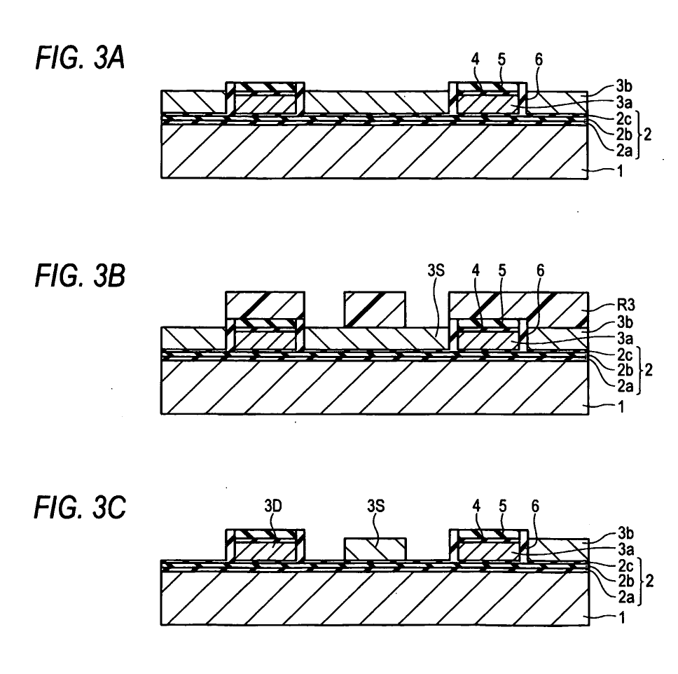

Successively, as shown in FIG. 3A, entire surface etching is conducted under the condition where the etching rate is substantially equal between the resist and the doped second layer amorphous silicon film 3b to planarize the doped second layer amorphous silicon film 3b.

Then, as shown in FIG. 3B, a resist pattern R3 for forming a peripheral circuit is formed. In this case, the resist pattern R3 is formed so as to cover the solid image pick-up device forming portion and a portion of the peripheral circuit portion.

Then, as shown in FIG. 3C, the doped second layer amorphous silicon film 3b above the photodiode region 30 is removed by etching using the resist pattern as R3 as a mask while leaving, the peripheral circuit pattern 3S.

Then, by removing the resist by ashing, a doped second layer amorphous silicon film 3b is formed so as to cover the solid image pick-up device forming portion and a portion of the peripheral circuit portion.

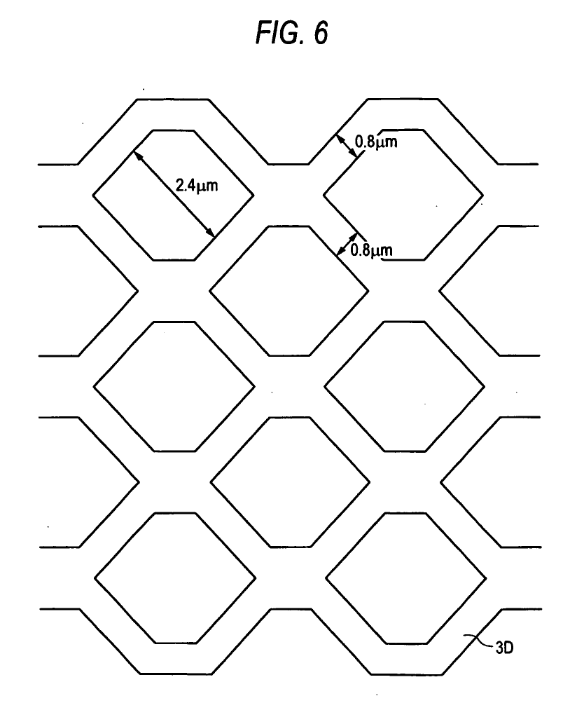

The second electrode comprising the doped second layer amorphous silicon film 3b is formed as descried above to form a charge transfer electrode with a planar surface. In this step, a honeycomb-shape dummy pattern 3D is left at the periphery of the substrate. The enlarged plane view is shown in FIG. 6. The dummy pattern 3D is in a network shape, which is preferably connected to the ground potential. This enables more stable connection.

Then, a pattern 71 for a light shield film and a BPSG film 72 of 700 nm thickness are formed thereover, and planarized by reflowing at 850° C. Then, an insulative film (passivation film) 73 comprising P—SiN and a planarized layer 74 comprising a transparent resin film are formed.

Then, a color filter 50, a planarized layer 61, a micro-lens 60, etc. are formed to obtain a solid image pick-up device as shown in FIG. 4 and FIG. 5.

According to the method described above, since the dummy pattern comprising the doped first layer amorphous silicon film is formed to the peripheral circuit portion, the surface level of the resist for etching-back can be formed in the same manner as that for the central portion, and pattern formation at high accuracy with no film reduction at the peripheral portion can be attained and operation characteristics of high reliability also in view of the function can be obtained.

As described above, with the constitution described above, since the dummy pattern is formed at the periphery of the substrate and the like where the pattern density of the first electrode is low, particularly, at the periphery of the substrate so that the surface level of the resist is not lowered upon coating the resist by spin coating, a solid image pick-up device of high reliability with no scattering of the characteristics can be formed.

Further, in the embodiment described above, the inter-electrode insulative film 6 was formed at the periphery of the first electrode by the vacuumed CVD method but the inter-electrode insulative film, instead, may be formed by thermal oxidation. That is, the thermal oxidation for the first electrode is conducted by using, as an oxidation preventive film, the two layered silicon nitride film of the silicon oxide film and the silicon nitride film to be used as the patterning mask for the first electrode and as the etching stopper upon planarization of the second electrode, the silicon oxide film is formed selectively on the side wall of the first electrode, which is used as the inter-electrode insulative film. In this case, it is necessary to previously form the resist pattern such that the width of the first electrode is increased by so much as the region to be oxidized.

### Second Embodiment

While the dummy pattern has been left and used as the ground line in the first embodiment, it may be removed after the resist etching-back treatment.

That is, the second embodiment is different from the first embodiment in that the resist pattern R3 for forming the peripheral circuit shown in FIG. 3B is constituted with a resist pattern R3′ not containing the dummy pattern.

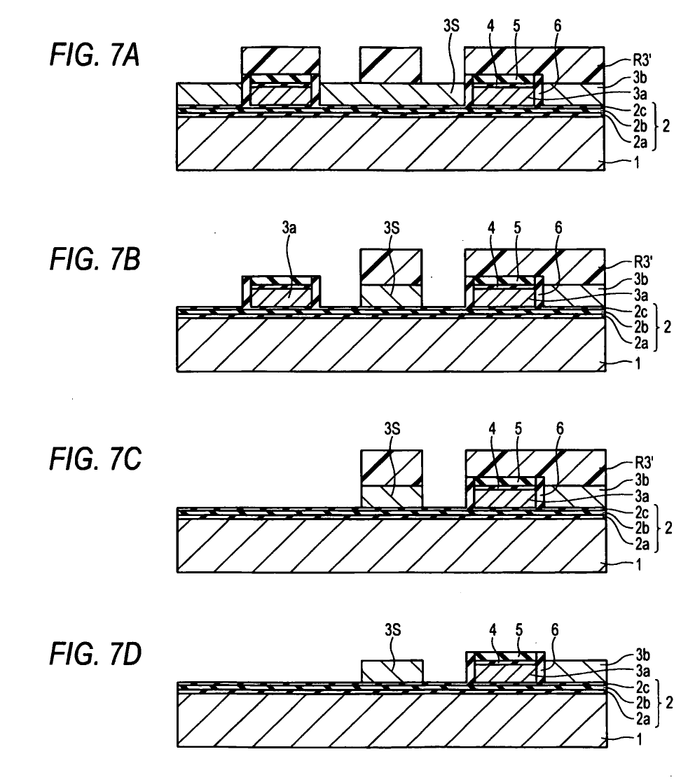

As shown in FIG. 7A, a resist pattern R3′ covering the peripheral circuit forming portion and the charge transfer portion are formed to the surface of the substrate planarized by etching-back. As apparent form the comparison with FIG. 3B, this embodiment is different only in that the resist pattern R3′ not containing the dummy pattern is used.

In this case, the resist pattern R3′ is formed so as to cover the solid image pick-up device forming portion and a portion of the peripheral circuit portion and expose the dummy pattern.

Then, as shown in FIG. 7B, the doped second layer amorphous silicon film 3b above the photodiode region 30 is removed by etching while leaving the peripheral circuit pattern 3S using the resist pattern R3′ as a mask.

Then, as shown in FIG. 7C, the silicon oxide film and silicon nitride film are successively removed by etching while leaving the resist pattern R3′ and the doped amorphous silicon film is removed to remove the dummy pattern.

Then, by removing the resist pattern R3′ by ashing, the doped second layer amorphous silicon film 3b is formed so as to cover the solid image pick-up device forming portion and a portion of the peripheral circuit portion.

According to this method, since the dummy pattern is removed, effect is not given on the circuit characteristics.

Further, the dummy pattern can be formed without lowering the surface level since it can be formed to density about equal with or higher than that of the first layer interconnection of the photoelectronic conversion portion.

### Third Embodiment

Also not described specifically in the embodiment described above, a field oxide film is formed in a frame-like shape at the chip peripheral portion so as to surround the effective image pick-up region thereof and it is preferably formed by a recess LOCOS method such that the surface level is identical between the photoelectronic conversion portion having a photosensor and the charge transfer portion.

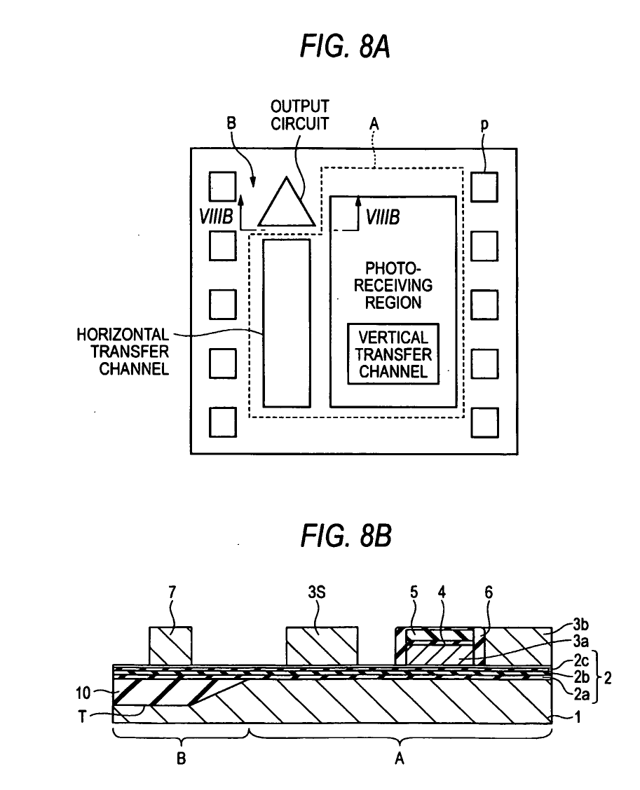

In the solid image pick-up device of this embodiment, the surface level of the field oxide film disposed to the peripheral circuit portion and the charge transfer portion is made about at the identical surface level with that of the photoelectronic conversion portion, and the entire substrate surface is planarized upon formation of the device region thereby improving the pattern accuracy by photolithography, by which the film reduction of the conductive film, particularly, the second layer conductive film caused upon making the charge transfer electrode into a single layered structure to form the charge transfer electrode and the peripheral circuit of a uniform film thickness. That is, according to the feature of the invention, as shown in FIGS. 8A and 8B, in a solid image pick-up device comprising a photoelectronic conversion portion, a charge transfer electrode for transferring charges generated in the photoelectronic portion and a peripheral circuit portion including an output circuit to be connected with the charge transfer portion, the surface of the field oxide film 10 formed in the frame-like shape so as to surround the effective image pick-up region (photoreceiving region) A is formed such that the level is identical with the surface level of the photoelectronic conversion portion having the photosensor and the charge transfer portion by a recess LOCOS method. FIG. 8A is an outlined view showing a solid image pick-up device chip in which the effective image pick-up region comprises a photoreceiving region containing a photoelectronic conversion portion, a vertical transfer channel (a portion of charge transfer portion) and a horizontal transfer channel (a portion of charge transfer portion), and an output circuit as a peripheral circuit O is formed to the outside thereof. p is a pad disposed at the chip periphery of the solid image pick-up device. Further, the peripheral circuit containing the output circuit corresponds to a non-image pick-up region B. 3S is a interconnection pattern for the peripheral circuit.

Further, as shown by outlined explanatory views in FIGS. 8A and 8B, on a silicon substrate 1, a plurality of photodiode regions constituting the photoelectronic conversion portion are formed, and the charge transfer portion for transferring signal charges detected by the photodiode is formed between photodiode regions. FIG. 8B shows a cross section taken along a line VIIIB-VIIIB in FIG. 8A.

Other portions than the field insulative film are formed in the same manner as the usual solid image pick-up device shown by the first embodiment.

That is, as shown in FIGS. 8A and 8B, a field oxide film 10 is formed in a trench T formed to the surface of a silicon substrate 1 so that the surface level of the substrate 1 and the surface level of the field oxide film 10 are identical.

A field oxide film 10 by selective oxidation is formed in the trench T formed to the surface of the silicon substrate 1, and CMP treatment is applied such that the step is 0 at the boundary between the non-image pick-up region B and the effective image pick-up region A. Then, a photoelectronic conversion portion including the photodiode is formed in the silicon substrate 1 and the photocurrent by the photodiode is read by way of the charge transfer portion.

In this embodiment, a silicon oxide film as the field oxide film 10 of 600 nm thickness is formed by selective oxidation in the trench T of about 600 nm depth formed to the device isolation region for the non-image pick-up region and the charge transfer portion of the silicon substrate 1. A horizontal transfer register that transfers signal charges in the horizontal direction, a signal processing circuit and an interconnection 7 are formed over the fielded oxide film 10.

With the constitution as described above, as shown in FIGS. 8A and 8B, since the pattern is formed on the planer surface, a pattern can be formed at an extremely high accuracy, and an extremely fine charge transfer portion can be formed. Further, also interconnections including the peripheral circuit portion can also be refined.

In the embodiment described above, while the field oxide film 10 by selective oxidation is formed in the trench T formed to the surface of the silicon substrate 1, a silicon oxide film or the like may also be filled in the trench.

According to the method of the invention, it is possible to prevent film reduction of the second layer silicon conductive film caused by the scattering of the surface level due to absence or presence of the underling pattern upon planarization by the resist etching-back method and form a solid image pick-up device of satisfactory charge transfer efficiency.

### INDUSTRIAL APPLICABILITY

As has been described above according to the method of the present invention, when the second layer conductive film is planarized by etching-back to form a charge transfer electrode of a single layered electrode structure, since the dummy pattern of the first layer conductive film is formed prior to etching-back, the pattern density is set to a predetermined value or more and the film reduction is prevented, scattering of the characteristics can be decreased to obtain a charge transfer electrode of high reliability, this is effective for the formation of fine and high sensitive solid image pick-up device.

The entire disclosure of each and every foreign patent application from which the benefit of foreign priority has been claimed in the present application is incorporated herein by reference, as if fully set forth.

1. A method of manufacturing a solid image pick-up device comprising a photoelectronic conversion portion, a charge transfer portion having a charge transfer electrode of a single layered electrode structure for transferring charges generated in the photoelectronic conversion portion and a peripheral circuit portion connected with the charge transfer portion, the method comprising:
a step of forming a pattern comprising a first layer silicon conductive film to a surface of a semiconductor substrate on which a gate oxide film is formed, the first layer silicon conductive film forming: a first electrode; and a first layer interconnection for the photoconductive conversion portion and the peripheral circuit portion;
a step of forming an insulative film as an inter-electrode insulative film at least to a side wall of the first electrode, so as to produce a first electrode/inter-electrode insulative film-formed semiconductor substrate;
a step of forming a second silicon conductive film to a surface of the first electrode/inter-electrode insulative film-formed semiconductor substrate, the second silicon conductive film being to form a second electrode, so as to produce a second silicon conductive film-formed semiconductor substrate;
a step of coating a resist over the second silicon conductive film-formed semiconductor substrate by a spin coating method; and
a step of planarizing the second layer silicon conductive film by a resist etching-back method,
wherein the pattern further comprises at least one dummy pattern, and the step of forming the pattern comprises a step of forming said at least one dummy pattern such that a surface level of the resist is not below a predetermined value over the semiconductor substrate.

2. A method of manufacturing a solid image pick-up device according to clam 1,
wherein said at least one dummy pattern are formed such that area density of said at least one dummy pattern is substantially equal to or more than that of the first layer interconnection for the photoelectronic conversion portion.

3. A method of manufacturing a solid image pick-up device according to claim 1,
wherein said at least one dummy pattern are formed such that distance between said at least one dummy pattern is substantially equal to or less than interconnection distance of the first layer interconnection for the photoelectronic conversion portion.

4. A method of manufacturing a solid image pick-up device according to claim 1, wherein further comprising a step of etching to remove partially said at least one dummy pattern after the step of planarizing.

5. A method of manufacturing a solid image pick-up device according to claim 1, wherein said at least one dummy pattern is electrically connected with each other.

6. A method of manufacturing a solid image pick-up device according to claim 5, wherein said at least one dummy pattern is in a network-shape.

7. A method of manufacturing a solid image pick-up device according to claim 1, wherein said at least one dummy pattern comprises at least one first dummy pattern located in a region adjacent with the second electrode, and each of said at least one first dummy pattern is an isolated pattern.

8. A method of manufacturing a solid image pick-up device according to claim 1, further comprising:
a step of forming a trench to the surface of the semiconductor substrate in a region for forming a field oxide film disposed to the peripheral circuit portion and the charge transfer portion, so as to surround an effective image pick-up region of the photoelectronic conversion portion, prior to forming the charge transfer portion;
a step of forming the field oxide film in the trench;
a surface planarization step of planarizing the surface of the semiconductor substrate to which the field oxide film is formed; and
a step of forming a device portion including the charge transfer electrode, the photoelectronic conversion portion and the peripheral circuit portion to the surface of the semiconductor substrate.

9. A method of manufacturing a solid image pick-up device according to claim 8,
wherein the step of forming the field oxide film comprises a selective oxidation (LOCOS) step.

10. A method of manufacturing a solid image pick-up device according to claim 8,
wherein the step of forming the field oxide film comprises a step of filling an insulative film to the trench by a CVD method.

11. A method of manufacturing a solid image pick-up device according to claim 8, wherein the surface planarization step of planarizing the surface of the semiconductor substrate comprises:
a step of coating a resist to the surface of the semiconductor substrate by a spin coating method; and
a step of planarization by a resist etching-back method

12. A method of manufacturing a solid image pick-up device according to claim 8, wherein the surface planarization step of planarizing the surface of the semiconductor substrate comprises a step of planarizing the surface of the semiconductor substrate by a CMP (Chemical mechanical polishing) method.

13. A method of manufacturing a solid image pick-up device according to claim 1, further comprising a step of forming a stopper layer as an etching stopper to a surface of the first electrode, prior to the step of forming the second silicon layer conductive film,
wherein the step of planarizing is a step of conducting etching-back by using the stopper layer as a stopper.

14. A solid image pick-up device comprising:
a photoelectronic conversion portion;
a charge transfer portion having a charge transfer electrode transferring charges generated in the photoelectronic conversion portion; and
a peripheral circuit portion connected to the charge transfer portion, wherein the charge transfer electrode has a single layered electrode structure comprising: a first electrode including a first layer silicon conductive film; and a second electrode including a second layer silicon conductive film formed by way of an inter-electrode insulative film covering a side wall of the first electrode,
an interconnection of the peripheral circuit portion comprises a first layer silicon conductive film,
wherein the solid image pick-up device further comprises at least one dummy pattern constituted so as not to be spaced by a predetermined distance or more from the interconnection of the peripheral circuit portion, and constituted to be at such a potential as giving no electric effect on the first electrode.

15. A solid image pick-up device according to claim 14 wherein said at least one dummy pattern is in a network shape.
